(19) United States
(12) Patent Application Publication
(10) Pub. No.: US 2008/0036026 A1
(43) Pub. Date: Feb. 14, 2008

(54) METAL LINE OF IMAGE SENSOR

(76) Inventor: Jeong Su Park, Seoul (KR)

Correspondence Address: SHERR & NOURSE, PLLC, 620 HERNDON PARKWAY, SUITE 200, HERNDON, VA, 20170, US

(21) Appl. No.: 11/775,635

(22) Filed: Jul. 10, 2007

(30) Foreign Application Priority Data
Jul. 11, 2006 (KR) 10-2006-0064861

(51) Int. Cl. H01L 31/00; H01L 21/00

(52) U.S. Cl. 257/459; 438/98; 257/E31.001

(57) ABSTRACT

A metal line of an image sensor and a method of fabricating a metal line of an image sensor having a transistor is disclosed, and in embodiments may include forming at least one interlayer insulating film in a semiconductor substrate having the transistor, forming a hole in the interlayer insulating film, filling the hole with a conductive material to form a contact, forming a metal line being connected to the contact on the interlayer insulating film, and forming a conductive spacer on sidewalls of the metal line. In embodiments, the conductive spacer may prevent diffused reflection and may prevent cracks from occurring at an edge of the metal line.

The present application claims priority under 35 U.S.C. 119 and 35 U.S.C. 365 to Korean Patent Application No. 10-2006-0064861 (filed on Jul. 11, 2006), which is hereby incorporated by reference in its entirety.

### BACKGROUND

An image sensor may be a semiconductor device to convert an optical image into an electrical signal. The image sensor may include a photosensitive part that may sense light and a logic circuit part that may process the sensed light into an electrical signal representing data. A CMOS image sensor adopts a switching method of providing as many MOS transistors as there are pixels by employing a CMOS technique and detecting the outputs several times using the MOS transistors.

Increasing the fill factor, which is the area of the photosensitive part occupied in the whole area of the image sensor, may improve the photosensitivity of certain image sensors. However, it may be difficult to increase the fill factor due to the limited area and because logic circuits cannot be removed from the device. Therefore, a focusing technique that focuses light on the photosensitive part by changing the path of light incident to regions other than the photosensitive part may be used in image sensors. This technique may be referred to as a micro lens formation technique. Further, an image sensor for implementing a color image may be equipped with a color filter array, which may include red, green, and blue color filters on the photosensitive part.

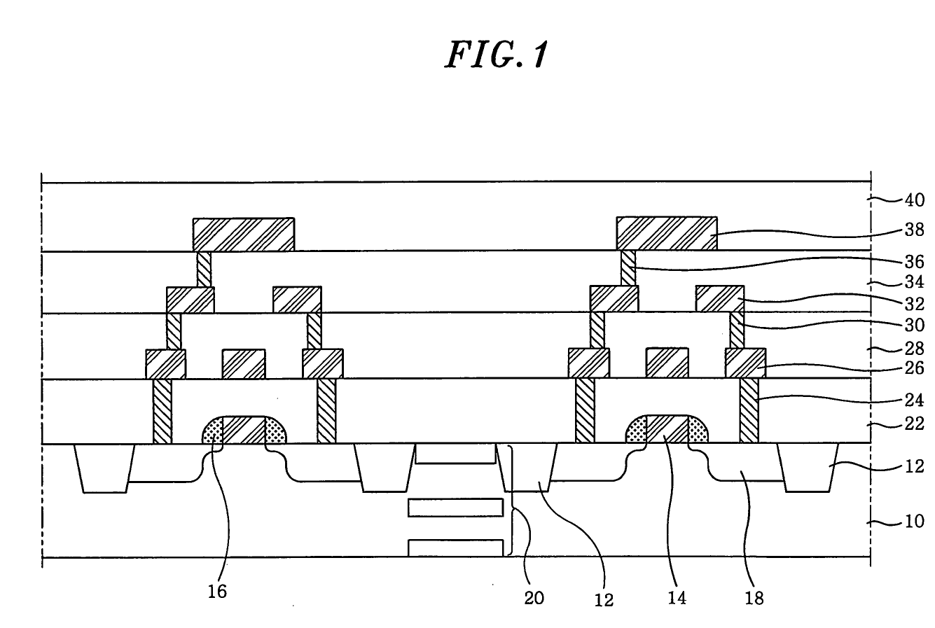

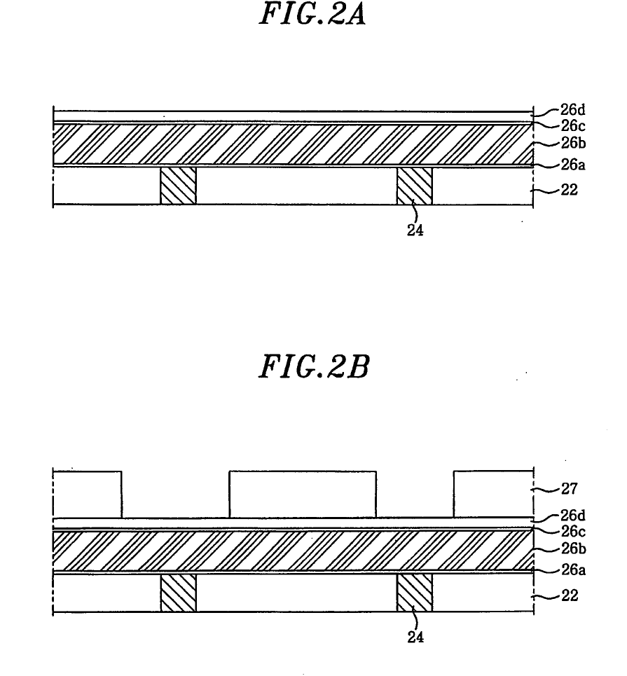

Example FIG. 1 is a vertical cross-sectional view illustrating an example of a metal line structure of a related art image sensor.

Referring to Example FIG. 1, a related art image sensor may include semiconductor substrate 10, photosensitive element 20 formed in semiconductor substrate 10, which may include photodiodes for sensing red, green, and blue light. The image sensor may also include field insulating films 12 formed in semiconductor substrate 10, which may insulate between the elements. A MOS transistor, which may be used for signal transfer, having gate electrode 14, spacers 16, and source/drain region 18 may be formed in semiconductor substrate 10 between field insulating films 12.

Furthermore, interlayer insulating films 22, 28, 34, and 40 of at least one multi-layer structure may be formed over a top surface of semiconductor substrate 10 in which photosensitive element 20 and the MOS transistor may be formed. Contact 24 and metal line 26 may be vertically connected to source/drain region 18 through the contact hole of interlayer insulating films 22, 28, 34, and 40. Vias 30 and 36 and metal lines 32 and 38 may be formed to connect between the metal lines.

Though not shown in the drawings, a passivation film, a planarization film, and an array of red, green, and blue color filters may also be formed over the interlayer insulating films.

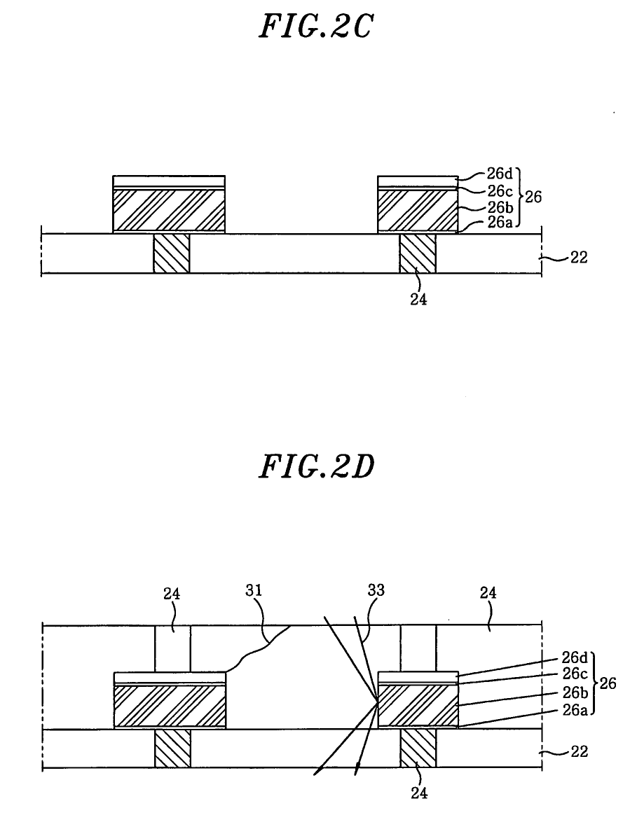

FIGS. 2a to 2d illustrate a related art processes of manufacturing a metal line of an image sensor.

An ion implant process may be performed on semiconductor substrate 10 to form photosensitive element 20, such as photodiodes for sensing red, green, and blue light.

A process, such as Shallow Trench Isolation (STI), may be performed to form field insulating films 12 for insulating between the elements in semiconductor substrate 10. The MOS transistor, having gate electrode 14, spacers 16, and source/drain region 18, may be formed in semiconductor substrate 10 between field insulating films 12.

Referring to Example FIG. 2a, BPSG, PSG, or the like may be deposited on semiconductor substrate 10 in which photosensitive element 20 and the MOS transistor may be formed, and may form first interlayer insulating film 22. Photolithography and etch processes employing a contact mask may then be performed, which may form the contact hole through which source/drain region 18 may be exposed through first interlayer insulating film 22. First interlayer insulating film 22 may be filled with a conductive material, such as tungsten (W), and may then undergo CMP to thereby form the contact 24. Conductive materials, such as Ti/AlCu/Ti/TiN 26a, 26b, 26c, and 26d, may be sequentially deposited on first interlayer insulating film 22, for example by a sputtering process.

Referring to Example FIG. 2b, a photolithography process may be performed to form a photoresist pattern 27. The photoresist pattern 27 may define a metal line region on the sequentially deposited Ti/AlCu/Ti/TiN 26a, 26b, 26c, and 26d.

Referring to Example FIG. 2c, Ti/AlCu/Ti/TiN 26a, 26b, 26c, and 26d, which may have been exposed by a photoresist pattern, may be patterned by a dry etch process, and may thereby form a metal line 26 connected to the contact 24 of first interlayer insulating film 22. The photoresist pattern may be removed by a process such as ashing.

Referring to Example FIG. 2d, an USG (Undopd Silicate Glass), a HDP (high-density plasma) oxide film, or the like may be deposited to form second interlayer insulating film 28. Photolithography and etch processes employing a contact mask may then be performed to form a via hole through which underlying metal line 26 may be exposed through second interlayer insulating film 28.

Second interlayer insulating film 28 may be filled with a conductive material such as tungsten (W) or the like, and CMP may be performed to form vias 30.

The processes of forming the interlayer insulating film, the via, and the metal line may be repeatedly performed to complete a multi-layer metal line of a related art image sensor. Accordingly, the signal from the MOS transistor can be transferred through the multi-layer metal line.

In a related art image sensor, however, edges metal lines 26, 32, 38 may remain exposed. Thus, light, which is incident at a specific angle as indicated by a reference numeral 33 in Example FIG. 2d, may cause diffused reflection on the sidewalls of the metal line. Accordingly, a situation may arise where the light is not incident on the surface of the substrate in which the photodiode may be formed.

Furthermore, in a related art image sensor, the conductive material may undergo dry etch to form the metal line. Thus, concentrated stress may occur because the metal line edge has an angle of 90 degrees. In this case, if additional annealing is performed, stress may be applied to the interlayer insulating film due to the difference in the coefficient of thermal expansion between the metal line and the interlayer insulating film. Consequently, crack 31 as shown in Example FIG. 2d may be generated due to the concentration of stress.

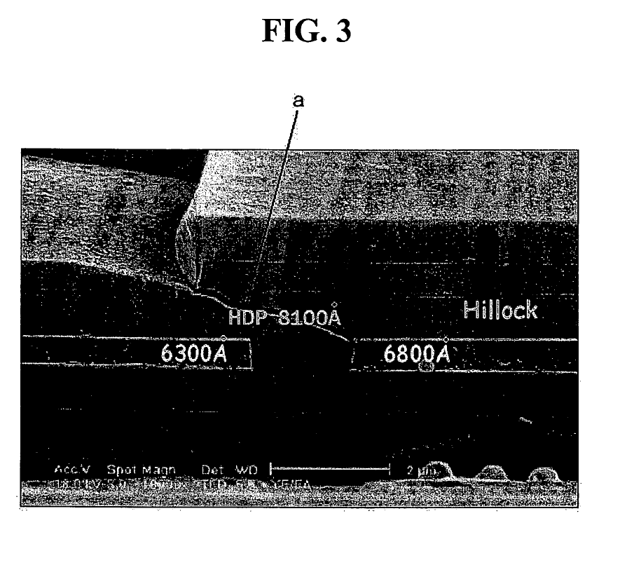

Example FIG. 3 is a photograph, taken by an optical microscope, of the experimental results to describe the crack problem that may occur in the metal line of a related art image sensor. A crack (a), which may be generated in the metal line of a related art image sensor, may begin at the metal line edge and is propagate to the interlayer insulating film, resulting in degraded performance of the image sensor.

### SUMMARY

Embodiments relate to an image sensor. More particularly, embodiments may relate to a metal line structure of an image sensor and a manufacturing method thereof, in which the occurrence of diffused reflection generated from metal line edges of an image sensor, such as Complementary Metal Oxide Semiconductor (CMOS), and cracks of an interlayer insulating film may be reduced or prevented.

Embodiments relate to a metal line structure of an image sensor in which a conductive spacer may be additionally formed on the sidewalls of a metal line, which may be capable of preventing diffused reflection and cracks occurring at the metal line edge.

Embodiments may also relate to a method of manufacturing a metal line of an image sensor, wherein a metal line may be patterned and a conductive spacer may be additionally formed on the sidewalls of the metal line, so that diffused reflection and cracks occurring at the metal line edge can be prevented.

According to embodiments, an image sensor may include a transistor, which may provide for signal transfer, an interlayer insulating film in a semiconductor substrate having the transistor formed thereon, a contact formed in a hole of the interlayer insulating film, a metal line formed on the interlayer insulating film and connected to the contact, and a conductive spacer formed on sidewalls of the metal line.

According to embodiments, a method of manufacturing an image sensor having a transistor, may include forming at least one interlayer insulating film in a semiconductor substrate having the transistor, forming a hole in the interlayer insulating film, filling the hole with a conductive material to form a contact, forming a metal line, which is connected to the contact, on the interlayer insulating film, and forming a conductive spacer on sidewalls of the metal line.

### DRAWINGS

Example FIG. 1 is a vertical cross-sectional view illustrating an example of a related art metal line structure.

Example FIGS. 2a to 2d are sectional views illustrating a related art processes of manufacturing a metal line.

Example FIG. 3 is a photograph of experimental results to describe the crack problem that may occur in the related art metal line.

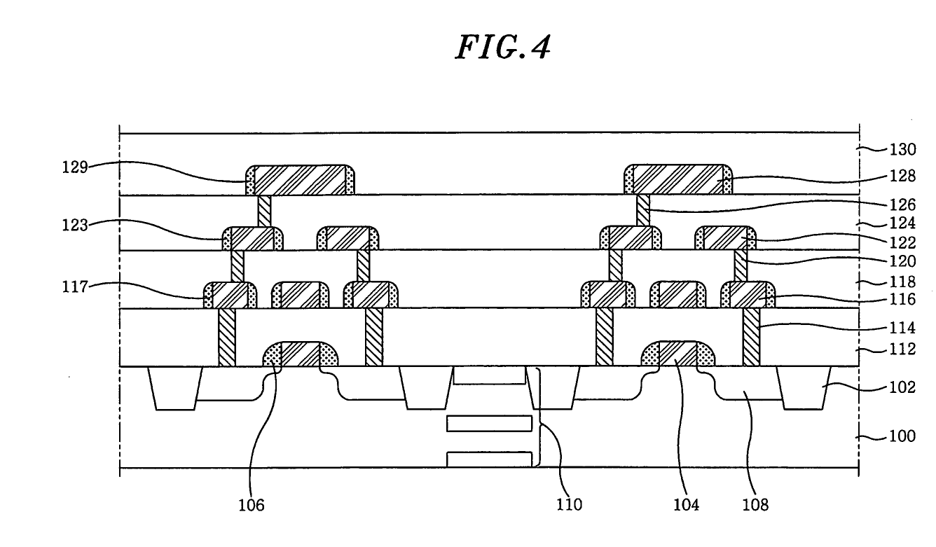

Example FIG. 4 is a vertical cross-sectional drawing illustrating a metal line structure of an image sensor according to embodiments.

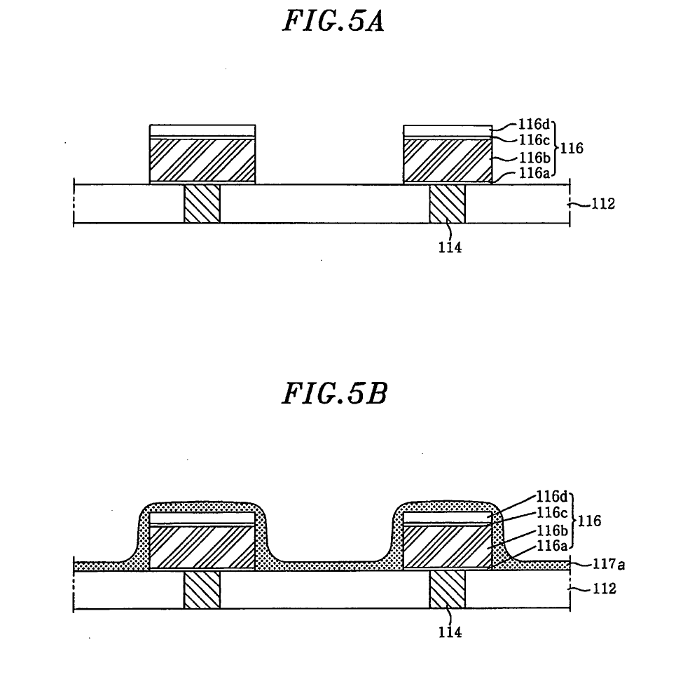

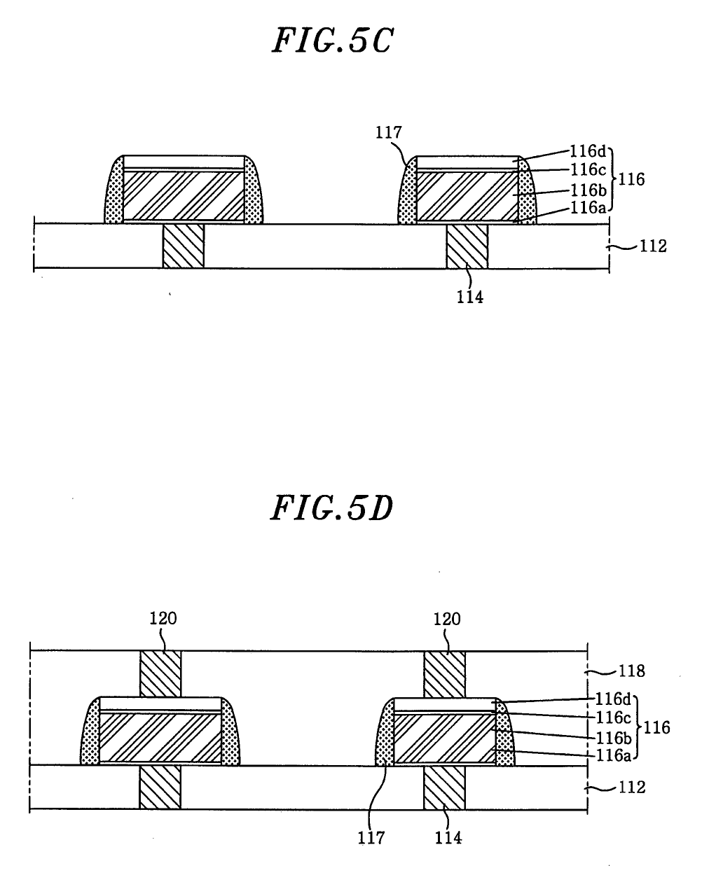

Example FIGS. 5a to 5d are sectional views illustrating a processes of manufacturing a metal line of an image sensor according to embodiments.

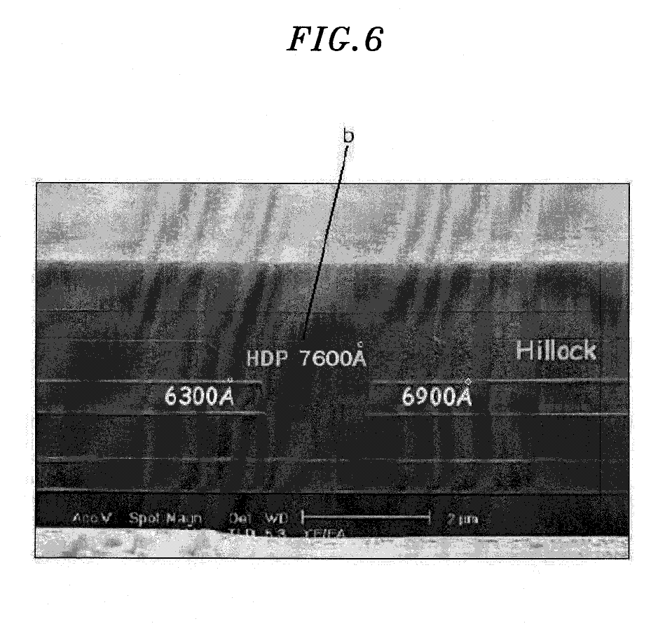

Example FIG. 6 is a photograph taken by an optical microscope, of the experimental results to describe the metal line of the image sensor according to embodiments.

### DESCRIPTION

Referring to Example FIG. 4, photosensitive element 110, such as photodiodes for sensing red, green, and blue light, may be formed in semiconductor substrate 100. Field insulating films 102, which may insulate between elements, may be formed in semiconductor substrate 100. A MOS transistor, which may provide for signal transfer, including gate electrode 104, spacer 106, and source/drain region 108, may be formed in semiconductor substrate 100, for example between the field insulating films 102.

Further, interlayer insulating films 112, 118, 124, and 130 of at least one multi-layer structure may be formed over semiconductor substrate 100 in which the photosensitive element 110 and the MOS transistor may be formed.

Contact 114 and metal line 116 may also be vertically connected to source/drain region 108, for example through a contact hole of lower interlayer insulating film 112. Vias 120 and 126 and metal lines 122 and 128 may be formed to connect the metal lines through the via hole of overlaying interlayer insulating films 118 and 124.

The image sensor further may include conductive spacers 117, 123, and 129, which may be formed on sidewalls of metal lines 116, 122, and 128, respectively. Therefore, the respective metal lines 116, 122, and 128 of the image sensor according to embodiments may have a substantially curved shape due to the conductive spacers 117, 123, and 129 formed on sidewalls of metal lines 116, 122, and 128. Thus, light, being incident at a specific angle, may not generate diffused reflections on the sidewalls of the metal line. Moreover, it may be possible to mitigate the concentration of stress at the metal line corner which may thereby decrease the occurrence of cracks.

Though not shown in the drawings, a passivation film, a planarization film, and an array of red, green, and blue color filters may also be formed over the interlayer insulating films.

A method of fabricating a metal line of an image sensor according to embodiments is described below with reference to the above drawings. Example FIGS. 5a to 5d illustrate a processes of manufacturing a metal line of an image sensor according to embodiments.

Though not shown in the drawings, according to embodiments, an ion implant process may be performed on the semiconductor substrate to form photosensitive elements, such as photodiodes for sensing red, green, and blue light. A process, such as STI, may then be performed to form the field insulating films for insulating between the elements in the semiconductor substrate.

The MOS transistor, including a gate electrode, a spacer, and a source/drain region, may be formed in the semiconductor substrate between the field insulating films.

Referring to Example FIG. 5a, BPSG, PSG, or any similar material may be deposited over semiconductor substrate 100 in which the photosensitive element 110 and the MOS transistor may be formed, and may form first interlayer insulating film 112. Photolithography and etch processes employing a contact mask may be performed, and may form a contact hole through which the source/drain region may be exposed through first interlayer insulating film 112.

First interlayer insulating film 112 may be filled with a conductive material such as tungsten (W) according to embodiments, and may undergo CMP, which may form contact 114. According to embodiments, conductive materials, such as Ti/AlCu/Ti/TiN 116a, 116b, 116c, and 116d, may be sequentially deposited over first interlayer insulating film, for example 112 by a process such as sputtering.

A photolithography process may then be performed to form a photoresist pattern, which may define a metal line region, on the sequentially deposited conductive layers (in embodiments, Ti/AlCu/Ti/TiN) 116a, 116b, 116c, and 116d. The conductive layers 116a, 116b, 116c, and 116d, which may be Ti/AlCu/Ti/TiN in embodiments, exposed by the photoresist pattern may be patterned by a dry etch process, which may form metal line 116 connected to contact 114 of first interlayer insulating film 112.

The photoresist pattern may then be removed by a process such as ashing.

Referring to Example FIG. 5b, conductive material 117a of about 1,500 Å in thickness may then be deposited on a surface, for example an entire surface, of first interlayer insulating film 112. Conductive material 117a may be material used to form a subsequent lateral spacer, and may include TiN in embodiments. TiN may be effective in preventing the transfer of a crack to an oxide film since the difference of a thermal expansion coefficient between the TiN and a metal stack is low.

Referring to Example FIG. 5c, conductive material 117a (for example TiN) may be etched by dry etch, such as etch back or the like, and may form conductive spacer 117 on the sidewalls of metal line 116. In embodiments, the dry etch process condition may include a mixed gas of SF₆ and CHF₃ and an etch rate of approximately 30 to 33 inch/1000 Å.

Referring to Example FIG. 5d, an USG (Undopd Silicate Glass), a HDP (high-density plasma) oxide film, or the like may be deposited on a surface, for example the entire surface, of first interlayer insulating film 112 on which metal line 116 and conductive spacer 117 may be formed. This may form second interlayer insulating film 118. Photolithography and etch processes employing a contact mask may then be carried out to form a via hole through which the underlying metal line 116 may be exposed through second interlayer insulating film 118. Second interlayer insulating film 118 may be filled with a conductive material, such as tungsten (W) or other conductive material according to embodiments, and CMP may be performed, thus forming vias 120.

According to embodiments, the processes of forming the interlayer insulating film, the via, and the metal line may be repeatedly performed to complete a multi-layer metal line of the image sensor for transferring a signal of the MOS transistor.

In accordance with embodiments, metal line 116, for example formed of Ti/AlCu/Ti/TiN, may be formed and conductive spacer 117, for example formed from TiN or the like, may be additionally formed on sidewalls of metal line 116 without an additional mask. Accordingly, a metal line edge may have a substantially curved shape, which may be a gently curved shape in embodiments, due to the conductive spacer 117. It may therefore be possible to reduce or prevent diffused reflection of light, which is incident at a specific angle. Furthermore, since the metal line corner may be substantially curved by conductive spacer 117, the concentration of stress may be mitigated. Accordingly, at the time of an additional thermal treatment process, the difference in the coefficient of thermal expansion between the metal line and the interlayer insulating film can be decreased and the occurrence of a crack at the metal line corner can be prevented.

Example FIG. 6 is a photograph taken by an optical microscope of experimental results to describe a structure of the metal line of the image sensor according to embodiments.

As represented as a reference numeral “b” in Example FIG. 6, in the metal line of the image sensor according to embodiments, a conductive spacer on sidewalls of a metal line may prevent the concentration of stress at a corner of the metal line. Therefore, the occurrence of a crack, which might begin at the metal line edge and be then propagated to the interlayer insulating film, can be prevented.

According to embodiments, after forming a metal line, conductive spacers may further be formed on sidewalls of the metal line without an additional mask. The conductive spacer may reduce diffused reflection of light, which may occur at an edge of the metal line. The curved and/or rounded shape of the metal line corner may also mitigate the concentration of stress. Accordingly, crack that may occur at the metal line corner may be prevented and a yield of the image sensor may be improved.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device, comprising:
a first interlayer insulating film formed over a semiconductor substrate, the semiconductor substrate having a transistor formed thereon;
a first contact formed in a hole of the first interlayer insulating film;
a first metal line formed over the first interlayer insulating film and electrically coupled to the first contact; and
first conductive spacers formed on sidewalls of the first metal line.

2. The device of claim 1, further comprising at least one second interlayer insulating layer formed over the first interlayer insulating layer, at least one second metal line formed over the second interlayer insulating layer, at least one via configured to electrically couple the first metal line to the second metal line, and second conductive spacers formed on sidewalls of the at least one second metal line.

3. The device of claim 2, further comprising further comprising a plurality of metal lines on each layer, wherein conductive spacers are formed on sidewalls of each metal line.

4. The device of claim 2, wherein the first and second conductive spacers comprise TiN.

5. The device of claim 2, further comprising a photosensor formed in the semiconductor substrate.

6. The device of claim 2, wherein the first and second conductive spacers have an inner surface coupled to the respective metal line, and an outer surface that is substantially curved.

7. The device of claim 6, wherein a maximum width of the first and second conductive spacers is approximately 1,500 Å.

8. The device of claim 1, wherein the first conductive spacers comprise TiN.

9. The device of claim 1, wherein at least a portion of the first conductive spacers comprise a substantially curved surface.

10. A method, comprising:
forming at least one interlayer insulating film over a semiconductor substrate, the semiconductor substrate having a transistor;
forming a hole in the at least one interlayer insulating film;
filling the hole with a conductive material to form a contact;
forming a metal line over the at least one interlayer insulating film, the metal line being electrically coupled to the contact; and
forming conductive spacers on sidewalls of the metal line.

11. The method of claim 10, further comprising forming a plurality of metal lines formed on the at least one interlayer insulating film, and forming conductive spacers on sidewalls of each of the plurality of metal lines.

12. The method of claim 10, further comprising repeatedly forming the interlayer insulating film, the contact, the metal line, and the conductive spacers to form a multi-layer structure.

13. The method of claim 12, wherein the conductive spacers are formed on sidewalls of each metal line of the multi-layer structure, and wherein the conductive spacer is made of TiN.

14. The method of claim 10, wherein forming the conductive spacers comprises forming at least a portion of the conductive spacers to be substantially curved.

15. The method of claim 14, further comprising forming a photosensor within the semiconductor substrate.

16. The method of claim 14, wherein the sidewall spacer is formed to have a maximum width at its base of approximately 1,500 Å.

17. The method of claim 10, wherein the at least one interlayer insulating film comprises a plurality of interlayer insulating films formed as a multilayer structure, each film being a layer, and wherein each layer comprises at least one metal line, conductive spacers on sidewalls of the at least one metal line, and at least one contact configured to electrically couple the metal lines on between respective layers.

18. The method of claim 17, wherein the conductive spacers comprise TiN.

19. The method of claim 10, wherein the conductive spacers comprise TiN.
